(19) United States
(12) Patent Application Publication
(10) Pub. No.: US 2020/0241340 A1
(43) Pub. Date: Jul. 30, 2020

(54) ARRAY SUBSTRATE AND DISPLAY DEVICE

(71) Applicants: HKC CORPORATION LIMITED, Shenzhen, Guangdong (CN); CHONGQING HKC OPTOELECTRONICS TECHNOLOGY CO., LTD., Chongqing (CN)

(72) Inventor: Yu-Jen CHEN, Jieshi, Banan District, Chongqing (CN)

(21) Appl. No.: 16/634,018

(22) PCT Filed: Dec. 13, 2017
(86) PCT No.: PCT/CN2017/115793

§ 371 Date: Jan. 24, 2020

(30) Foreign Application Priority Data
Aug. 1, 2017 (CN) 201710646119.X

(51) Int. Cl. G02F 1/1368; H01L 27/12; H01L 29/786; G02F 1/1333; G02F 1/1362

(52) U.S. Cl. CPC G02F 1/1368; H01L 27/1222; H01L 27/1225; H01L 27/124; H01L 27/1255; H01L 29/78669; G02F 2001/136295; H01L 29/7869; G02F 1/133345; G02F 1/136286; G02F 2201/123; G02F 2201/121; H01L 29/78678

(57) ABSTRACT

An array substrate and a display device are provided. The array substrate comprises a substrate, a switch assembly, a metal lines, a pixel electrode and a plurality of pixel units. The switch assembly is disposed on the substrate, and the switch assembly comprises a plurality of transistors. The pixel electrode comprises a plurality of line-shaped branches. The branches comprises a horizontal branch and a vertical branch perpendicular to each other, and a drain line of one of the transistors is disposed under one of the horizontal branchs closest to the transistor. Each pixel unit comprises a plurality of display domains, and the display domains of each of the pixel units are symmetrical with respect to the horizontal branch or the vertical branch. A projection of the metal lines on the array substrate overlaps with a vertical projection of the horizontal or vertical branch on the array substrate.

### BACKGROUND

### Technical Field

This disclosure relates to a technical field of a liquid crystal display, and more particularly to an array substrate and a display device.

### Related Art

A liquid crystal display panel is a key component of a liquid crystal display, and the liquid crystal display is the most widely used display in the present market.

At present, the liquid crystal display panel is gradually developed in the direction toward the large size or high resolution. More particularly, the resolution of the liquid crystal display panel cannot satisfy the consumer's requirement.

The liquid crystal display panel comprises thin film transistors and pixel electrodes. The drain of the thin film transistor is electrically connected to the pixel electrode through the metal pad. The increasing of the resolution of the liquid crystal display panel certainly causes the dimensional reduction of the pixel electrode. Meanwhile, with the increase of the amount of the metal lines, the aperture ratio is obviously decreased. In addition, after the pixel electrode becomes small and because the space for wiring is limited, some pads extends into the display area, so that the electric field and the surface features of the area which the liquid crystal of the opening region are disposed on become more complicated. Under the effect of the external force, the liquid crystal here may present a chaotic arrangement, the liquid crystal cannot be timely and orderly arranged during frame switching. At this time, the image quality of the liquid crystal display panel encounters problems.

### SUMMARY

An embodiment of this disclosure provides an array substrate and a display device, which can improve the resolution of the liquid crystal panel and enhance the image quality.

The disclosure provides an array substrate comprises a substrate, a switch assembly, a metal lines, a pixel electrode and a plurality of pixel units. The switch assembly is disposed on the substrate, and the switch assembly comprises a plurality of transistors. The pixel electrode comprises a plurality of line-shaped branches. Each branch comprises a horizontal branch and a vertical branch perpendicular to each other, and a drain line of each of the transistors is disposed under the horizontal branch closest to the transistor. Each of the pixel units comprises a plurality of display domains, and the display domains of each of the pixel units are symmetrical with respect to the horizontal branch or the vertical branch. From a view perpendicular to the array substrate, a projection of each metal line on the array substrate overlaps with a projection of each horizontal branch or each vertical branch on the array substrate.

Optionally, each of the pixel unit further comprises a common electrode line and a storage capacitor, and the common electrode lines of the pixel units in the same row are connected to each other. An insulating layer is disposed between a layer where the metal lines are disposed and a layer where the common electrode lines are disposed, and each common electrode line and each metal line are respectively functioned as a first electrode and a second electrode of the storage capacitor.

Optionally, each of the common electrode line comprises a first common electrode line, and, from a view perpendicular to the array substrate, a projection of the first common electrode line on the array substrate overlaps with a projection of each metal line on the array substrate.

Optionally, each of the common electrode line further comprises a second common electrode line disposed on at least one lateral side portion of each pixel unit.

Optionally, each of the common electrode line and a gate of each transistor are disposed in the same layer.

Optionally, each of the metal lines and a drain of each transistor are disposed in the same layer.

Optionally, the insulating layer is a gate insulating layer of each transistor, a passivation layer is disposed between the layer where the metal lines are disposed and a layer where the pixel electrode is disposed. The passivation layer is provided with a through hole, and the metal lines are electrically connected to the pixel electrode via the through hole.

Optionally, from a view perpendicular to the array substrate, a projection of the through hole on the array substrate overlaps with the projection of each horizontal branch and/or each vertical branch on the array substrate.

Optionally, each of the pixel units comprises a first display domain, a second display domain, a third display domain and a fourth display domain. The first display domain and the second display domain are disposed in the same row. The third display domain and the fourth display domain are disposed in the same row. The first display domain and the third display domain are disposed in the same column, and the second display domain and the fourth display domain are disposed in the same column.

Optionally, from a view perpendicular to the array substrate, the projection of the through hole on the array substrate is overlapped with at least one among a gap between the first display domain and the second display domain, a gap between the first display domain and the third display domain, a gap between the second display domain and the fourth display domain and a gap between the third display domain and the fourth display domain.

Optionally, each of the metal lines is disposed within a gap between two adjacent display domains.

Optionally, each transistor is a metal oxide transistor, a low-temperature polysilicon transistor, or an amorphous silicon transistor.

Optionally, a width of each metal line is in a range of greater than or equal to 2 micrometers and smaller than or equal to 3 micrometers.

The disclosure also provides a display device comprising a control circuit and a display panel, and the display panel comprises the above-mentioned array substrate.

In this disclosure, the drain line of the transistor is disposed under the horizontal branch closest to said transistor to avoid the size reducing of the pixel electrode resulted from that the drain of the transistor is connected to the pixel electrode through the metal pad, and to avoid the chaotic arrangement of the liquid crystal resulted from the pad extending into the display area. It is unnecessary to occupy an additional area of the display area of the pixel unit, and the aperture ratio of the pixel is then increased. In each pixel unit, the liquid crystal in the gap region between the two adjacent display domains is affected by the electric fields of said two adjacent display domains. In this disclosure, the display domains of each of the pixel units are symmetrical with respect to each horizontal branch or each vertical branch, so as to eliminate the influence of a not-uniform electric field on the liquid crystal molecules.

### BRIEF DESCRIPTION OF THE DRAWINGS

The embodiments will become more fully understood from the detailed description and accompanying drawings, which are given for illustration only, and thus are not limitative of the present invention, and wherein:

FIG. 1 is a partial top view showing an exemplary array substrate;

FIG. 2 is an optical inspecting image showing the area of FIG. 1 indicated by the dashed-line frame 16;

FIG. 3 is a partial top view showing an array substrate according to one embodiment of this disclosure;

FIG. 4 is an optical inspecting image showing the area of FIG. 3 indicated by the dashed-line frame 41;

FIG. 5 is a partial top view showing another array substrate according to one embodiment of this disclosure;

FIG. 6 is a cross-sectional view along an AA′ line of FIG. 5;

FIG. 7 is a partial top view showing still another array substrate according to one embodiment of this disclosure;

FIG. 8 is a partial top view showing yet still another array substrate according to one embodiment of this disclosure;

FIG. 9 is a partial top view showing yet still another array substrate according to one embodiment of this disclosure;

FIG. 10 is a partial top view showing yet still another array substrate according to one embodiment of this disclosure; and

FIG. 11 is a schematic structure view showing a display panel according to one embodiment of this disclosure.

### DETAILED DESCRIPTION OF THE INVENTION

The embodiments of the invention will be apparent from the following detailed description, which proceeds with reference to the accompanying drawings, wherein the same references relate to the same elements.

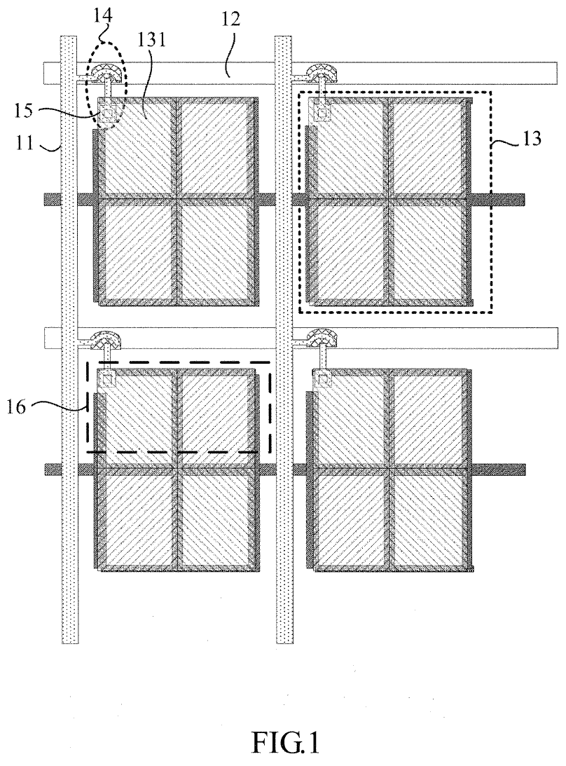

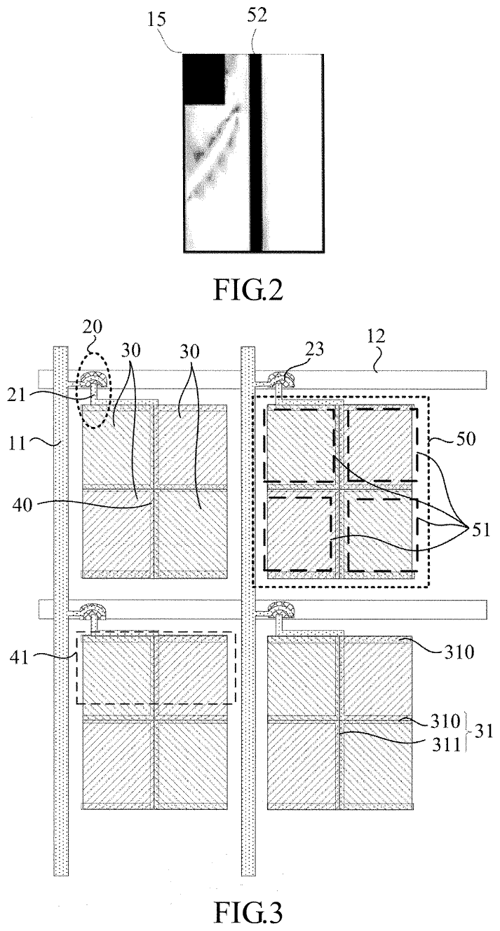

FIG. 1 is a partial top view showing an exemplary array substrate. Referring to FIG. 1, a plurality of pixel units 13 are defined by the data lines 11 and the scan lines 12 which are insulated from and crossed to each other. A transistor 14 a pixel electrode 131 of a pixel unit 13 is connected by a pad 15. The pad 15 extends into a display area of the pixel unit 13. On one hand, such configuration may decrease the aperture ratio of the pixel unit 13. On the other hand, it may affect the electric field around a display area. FIG. 2 is an optical inspecting image showing the area indicated by the dashed line frame 16 in FIG. 1. Referring to FIG. 2, it is found that the area where the pad 15 is located is opaque such that the aperture ratio of the pixel unit is decreased, and the liquid crystal around the pad 15 presents in a chaotic arrangement to cause a poor display. During frame switching, the liquid crystal cannot be timely and orderly arranged, and the after-image phenomenon appears. The symbol 52 denotes the opaque area where a common electrode line is located.

FIG. 3 is a partial top view showing an array substrate according to one embodiment of this disclosure. Referring to FIG. 3, the array substrate provided by the embodiment of this disclosure comprises: a substrate (not shown in the drawing), a switch assembly, which is disposed on the substrate and comprises a plurality of transistors 20, and a pixel electrode 30 and metal lines 40. The pixel electrode 30 comprises a plurality of line-shaped branches 31 each comprising a horizontal branch 310 and a vertical branch 311 which is perpendicular to the vertical branch 311. A drain line 21 of each transistor 20 is disposed under the horizontal branch 310 closest to the transistor 20. The drain 21 of each transistor 20 is connected to the pixel electrode 30 through the drain line 21 (the drain line and the drain refer to the same symbol 21). The array substrate comprises a plurality of pixel units 50 each comprising a plurality of display domains 51. The display domains 51 of each pixel unit 50 are symmetrical with respect to each horizontal branch 310 or each vertical branch 311. From a view perpendicular to the array substrate 10, the projection of each metal line 40 overlaps with the projection of each horizontal branch 310 or each vertical branch 311.

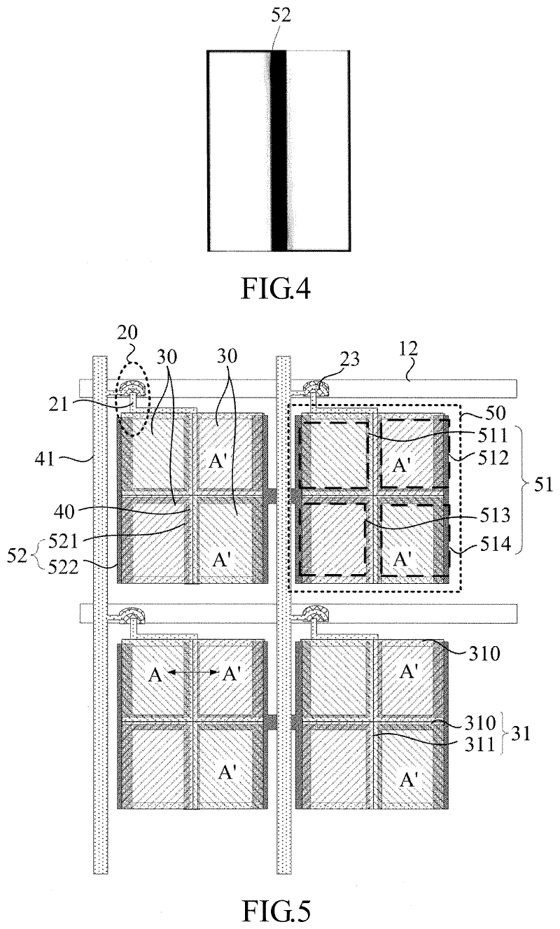

In this embodiment of this disclosure, the drain line 21 of each transistor 20 is disposed under the horizontal branch 310 closest to said each transistor 20 to avoid the size reducing of the pixel electrode 30 resulted from that the drain of the transistor 20 connected to the pixel electrode 30 through a metal pad, and to avoid a chaotic arrangement of the liquid crystal resulted from that the pad extends into the display area. It is unnecessary to occupy an additional area of the display area of the pixel unit, and the aperture ratio of the pixel is increased. In the pixel unit 50, the liquid crystal in the gap region between the two adjacent display domains 51 is affected by the electric fields of said two adjacent display domains 51, such that the gap region between the adjacent two display domains 51 in the pixel unit 50 is in a dark state. In this disclosure, each of the metal lines 40 connecting the drain 21 of each transistor 20 to the pixel electrode 30 is disposed in the gap between the two adjacent display domains 51, such that the disposing of the metal lines 40 needs not to occupy an additional area of the display area of the pixel unit 50, so as to increase the aperture ratio of the pixel. In the embodiment of this disclosure, the display domains 51 of each of the pixel units 50 are symmetrical with respect to each horizontal branch 310 or each vertical branch 311, so as to eliminate the influence of a not-uniform electric field on the liquid crystal molecules. FIG. 4 is an optical inspecting image showing the area indicated by the dashed line frame 41 in FIG. 3. Comparing FIG. 2 to FIG. 4, it shows that the light-outputting area of the display frame in FIG. 4 is greater than that of the display frame in FIG. 2, such that the problem of the reducing of the aperture ratio of the pixel unit resulted from the connection between the drain and the pixel electrode is avoided. In addition, referring to FIG. 4, it is not found a blur image and after-image phenomenon occurred in the whole display area of the pixel unit. From a view perpendicular to the array substrate 10, the projection of each metal line 40 is disposed in the projection of the gap between the two adjacent display domains 51. In the embodiment of this disclosure, the display domains 51 of each of the pixel units 50 are symmetrical with respect to each horizontal branch 310 or each vertical branch 311. Accordingly, the influence of a not-uniform electric field on the liquid crystal molecules is eliminated. Hence, the problem of an irregular arrangement of the liquid crystal, which is resulted from a disturbing of the surrounding electric field induced by the pad 15 (which is shown in FIG. 2), will not occur. Only the area where the common electrode line 52 is located becomes opaque.

It should be noted that in the embodiment of this disclosure, the transistor 20 may be a metal oxide transistor, a low-temperature polysilicon transistor, an amorphous silicon transistor or the like, but the type of the transistor is not limited herein. The gate of each transistor 20 is connected to the scan line 12 (in FIG. 3, the gate of the transistor 20 is a portion of the scan line 12) and receives a scan signal. A source 23 of each transistor 20 is connected to the data line 11 and receives a data signal. The drain 21 of each transistor 20 is connected to the pixel electrode 30 through the metal line 40. Optionally, the width of the metal lines 40 may be configured to be in the range of greater than or equal to 2 micrometers and smaller than or equal to 3 micrometers. Exemplarily, the pixel unit 50 of FIG. 3 is divided into four display domains 51, and the metal lines 40 are disposed in all gaps between the display domains 51.

Optionally, the metal lines 40 and the drain 21 of each transistor 20 are disposed in the same layer. The material of the metal lines 40 may be identical to the material of the drain 21 of each transistor 20. In other words, the metal lines 40 and the drain 21 of each transistor 20 may be formed by patterning the same material in the same process, thereby simplifying the manufacturing process and reducing the manufacturing costs.

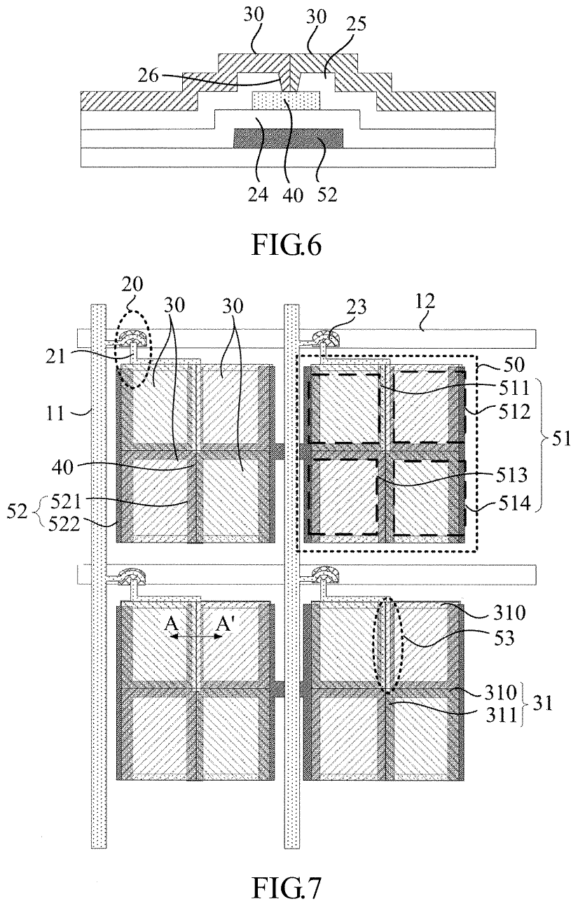

FIG. 5 is a partial top view showing another array substrate according to one embodiment of this disclosure, and FIG. 6 is a cross-sectional view along the A-A′ line in FIG. 5.

Referring to FIGS. 5 and 6 and based on the above-mentioned embodiment, each of the pixel unit 50 of the array substrate provided by the embodiment of this disclosure further comprises a common electrode line 52 and a storage capacitor (not shown in the drawing). In addition, the common electrode lines 52 of the pixel units 50 in the same row are connected to each other. Referring to FIG. 6, the common electrode line 52 and the metal lines 40 are disposed in different layers and insulated from each other. An insulating layer 24 is disposed between the common electrode line 52 and the metal lines 40, and each common electrode line 52 and each metal line 40 are respectively functioned as a first electrode and a second electrode of each storage capacitor. A passivation layer 25 is disposed between each of the metal lines 40 and the pixel electrode 30 and is provided with a through hole 26. Each of the metal lines 40 is connected to the pixel electrode 30 through the through hole 26. Form a view perpendicular to the array substrate 10, the projection of the through hole 26 at least overlaps with the projection of the gap between the two adjacent display domains 51. In other words, form a view perpendicular to the array substrate 10, the projection of the through hole 26 overlaps with the projection of each horizontal branch 310 or each vertical branch 311.

It should be noted that the storage capacitor is advantageous to keeping a potential level in the liquid crystal capacitor of the liquid crystal display panel, and to lengthen the display time of the display panel, and to enhance the stability of the display effect of the display panel. In the embodiment of this disclosure, the capacitance of the storage capacitor can be changed by adjusting the distance between the common electrode line 52 and the metal lines 40. For example, according to the requirement of the actual product on the capacitance of the storage capacitor, the position of the layer where the common electrode line 52 and the metal lines 40 are located can be designed, so as to control the distance between the common electrode line 52 and the metal lines 40.

Optionally, referring to FIG. 6, the insulating layer 24, disposed between the layer where the metal lines 40 are located and the layer where the common electrode lines 52 are located, may be the gate insulating layer of each transistor 20. Compared with the conventional technology, in which the common electrode line is used as the first electrode of the storage capacitor, the pixel electrode 30 is used as the second electrode of the storage capacitor, and the gate insulating layer and the passivation layer of the transistor 20 are successively disposed between the layer where the pixel electrode 30 is located and the layer where the common electrode line 52 is located. In other words, the gate insulating layer and the passivation layer are disposed between the first electrode and the second electrode of the storage capacitor. In the array substrate 10 provided by the embodiment of this disclosure, the first electrode and the second electrode of the storage capacitor may be only provided with the gate insulating layer of the transistor 20. Hence, such configuration in this disclosure can enlarge the storage capacitor of the array substrate 10, and enhance the stability of the display effect of the display panel.

Optionally, referring to FIG. 5, each of the common electrode line 52 comprises a first common electrode line 521. Form a view perpendicular to the array substrate, the projection of the first common electrode line 521 overlaps with the projection of each of the metal lines 40.

Optionally, the common electrode line 52 further comprises a second common electrode line 522 disposed on at least one lateral side portion of the pixel unit 50.

Optionally, the common electrode line 52 and the gate of each transistor 20 are disposed in the same layer. While the gate of the transistor 20 is being formed, the common electrode line 52 is formed through patterned etching, thereby simplifying the manufacturing process and decreasing the manufacturing costs.

It should be noted that in the configuration which is exemplarily shown in FIG. 5, each pixel unit 50 comprises four display domains. In other embodiments, the number of the display domains may be varied with the design requirement of the actual product. Referring to FIG. 5, each pixel unit 50 comprises a first display domain 511, a second display domain 512, a third display domain 513 and a fourth display domain 514, arranged in a 2×2 matrix. The first display domain 511 and the second display domain 512 are disposed in the same row, the third display domain 513 and the fourth display domain 514 are disposed in the same row, the first display domain 511 and the third display domain 513 are disposed in the same column, and the second display domain 512 and the fourth display domain 514 are disposed in the same column. In the embodiment of this disclosure, it is possible to configure that, from a view perpendicular to the array substrate 10, the projection of the through hole 26 overlaps with the gap between the first display domain 511 and the second display domain 512, the gap between the first display domain 511 and the third display domain 513, the gap between the second display domain 512 and the fourth display domain 514 or the gap between the third display domain 513 and the fourth display domain 514, so as to increase the areas of the two opposing electrodes of the storage capacitor facing to each other.

It should be noted that, in the embodiment of this disclosure, it only requires that, from a view perpendicular to the array substrate 10, the projection of the metal lines 40 is still disposed in the projection of at least one among the gap between the first display domain 511 and the second display domain 512, the gap between the first display domain 511 and the third display domain 513, the gap between the second display domain 512 and the fourth display domain 514, and the gap the third display domain 513 and the fourth display domain 514, and requires that, from a view perpendicular to the array substrate 10, the projection of the through hole 26 overlaps with at least one among the gap between the first display domain 511 and the second display domain 512, the gap between the first display domain 511 and the third display domain 513, the gap between the second display domain 512 and the fourth display domain 514, and the gap between the third display domain 513 and the fourth display domain 514.

Referring to the array substrate shown in FIG. 7, from a view perpendicular to the array substrate 10, the of each metal line 40 is disposed in the projection of the gap between the first display domain 511 and the second display domain 512 on the array substrate. From a view perpendicular to the array substrate 10, the projection of the through hole (the area indicated by the dashed line frame 53) on the array substrate overlaps with the gap between the first display domain 511 and the second display domain 512.

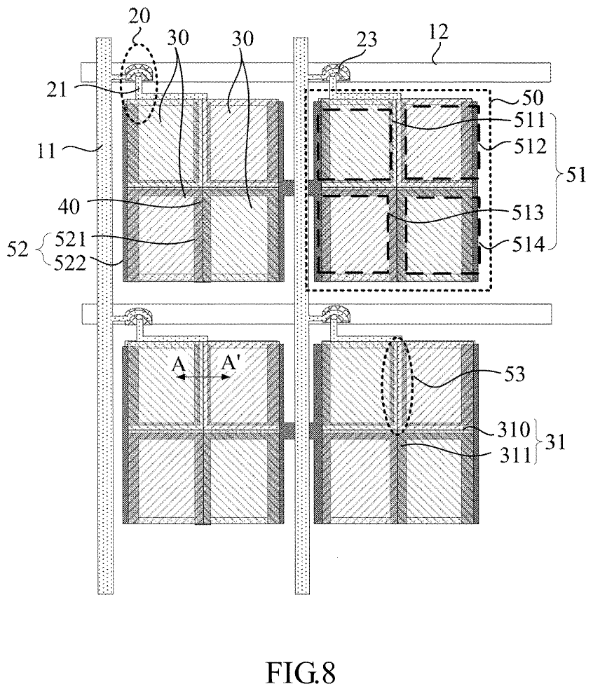

In the array substrate as shown in FIG. 8, from a view perpendicular to the array substrate 10, the projection of each metal line 40 on the array substrate is disposed in the vertical projection of the gap between the first display domain 511 and the second display domain 512, the gap between the first display domain 511 and the third display domain 513, and the gap between the second display domain 512 and the fourth display domain 514 on the array substrate. From a view perpendicular to the array substrate 10, the vertical projection of the through hole (the area indicated by the dashed line frame 53) on the array substrate only overlaps with the gap between the first display domain 511 and the second display domain 512.

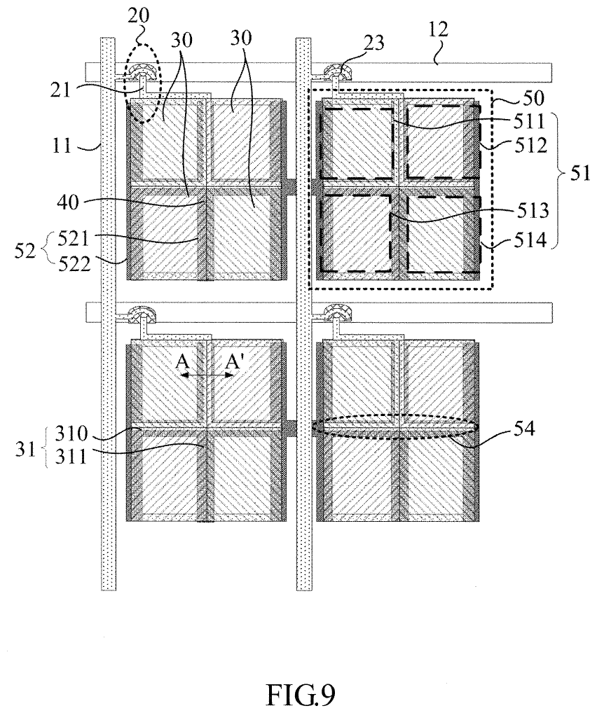

In the array substrate as shown in FIG. 9, from a view perpendicular to the array substrate 10, the vertical projection of the metal lines 40 on the array substrate is disposed in the vertical projections of the gap between the first display domain 511 and the second display domain 512, the gap between the first display domain 511 and the third display domain 513, and the gap between the second display domain 512 and the fourth display domain 514 on the array substrate. From a view perpendicular to the array substrate 10, the vertical projection of the through hole (the area indicated by the dashed line frame 54) on the array substrate may further be configured to overlap with the gap between the first display domain 511 and the third display domain 513 and the gap between the second display domain 512 and the fourth display domain 514.

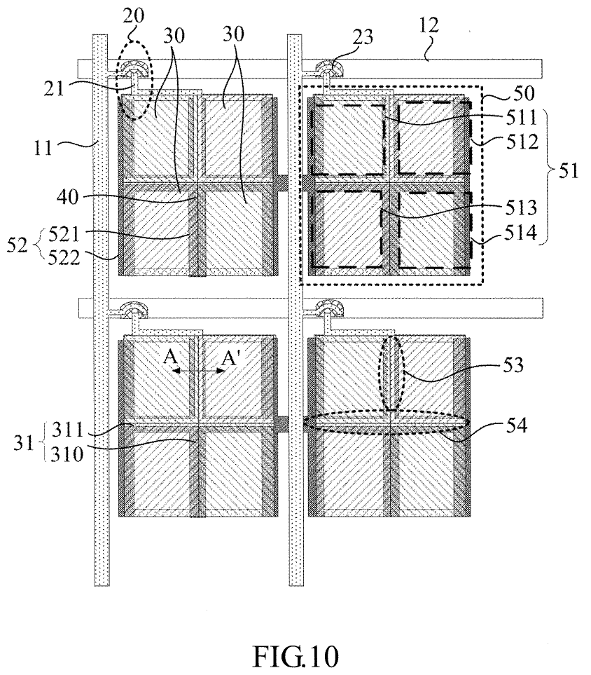

In the array substrate as shown in FIG. 10, from a view perpendicular to the array substrate 10, the vertical projection of the metal lines 40 on the array substrate is disposed in the vertical projection of the gap between the first display domain 511 and the second display domain 512, the gap between the first display domain 511 and the third display domain 513, and the gap between the second display domain 512 and the fourth display domain 514 on the array substrate. From a view perpendicular to the array substrate 10, the vertical projection of the through hole (the areas indicated by the dashed line frame 53 and the dashed line frame 54) on the array substrate may further be configured to overlap with the gap between the first display domain 511 and the second display domain 512, the gap between the first display domain 511 and the third display domain 513, and the gap between the second display domain 512 and the fourth display domain 514. By adjusting the overlapping area of the gap between the metal lines 40 and each of the display domains and the overlapping area between the through hole 26 and each of the display domains, it is possible to control the capacitance of the storage capacitor, whereas the increase of the capacitance of the storage capacitor is advantageous to keep the potential level of the liquid crystal capacitor and to compensate the parasitic capacitor.

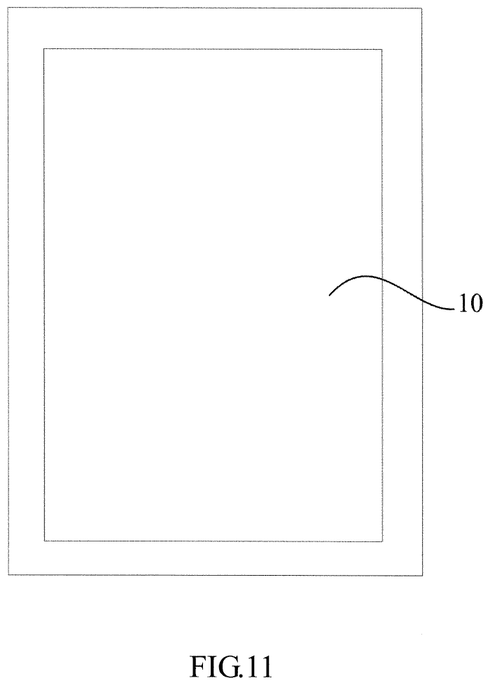

The embodiment of this disclosure further provides a display device comprising a control circuit and a display panel, and the display panel comprises the array substrate associated with the above-mentioned technical solution. FIG. 11 is a schematic structure view showing a display panel provided by the embodiment of this disclosure.

Referring to FIG. 11, the display panel comprises the array substrate 10 of the above-mentioned embodiment. The display panel provided by the embodiment of this disclosure comprises the array substrate 10 of the above-mentioned embodiment, so the display panel provided by the embodiment of this disclosure also possess the useful effects mentioned in the above-mentioned embodiment, and detailed descriptions thereof will be omitted.

In this disclosure, the display panel can be, for example, an LCD panel, an OLED display panel, a QLED display panel, a curved display panel, or any of other display panels.

When the display device is a LCD device, the display device may be a TN, OCB, VA or curved type liquid crystal display device, but is not limited thereto.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An array substrate, comprising:
a substrate;
a switch assembly disposed on the substrate, wherein the switch assembly comprises a plurality of transistors;
metal lines;
a pixel electrode comprising a plurality of line-shaped branches, wherein each of the branches comprises a horizontal branch and a vertical branch perpendicular to each other, and a drain line of each transistor is disposed under the horizontal branch which is closest to said each transistor; and
a plurality of pixel units, wherein each of the pixel units comprises a plurality of display domains, and the display domains of each of the pixel units are symmetrical with respect to the horizontal branch or the vertical branch;
wherein, from a view perpendicular to the array substrate, a projection of each of the metal lines overlaps with a projection of each horizontal branch or each vertical branch.

2. The array substrate according to claim 1, wherein:
each of the pixel unit further comprises a common electrode line and a storage capacitor, and the common electrode lines of the pixel units in the same row are connected to each other;
an insulating layer is disposed between a layer where the metal lines are disposed and a layer where the common electrode lines are disposed, and each common electrode line and the each metal line are respectively functioned as a first electrode and a second electrode of each storage capacitor; and
each common electrode line comprises a first common electrode line, and, from a view perpendicular to the array substrate, a projection of the first common electrode line overlaps with a projection of the each metal line.

3. The array substrate according to claim 2, wherein each common electrode line further comprises a second common electrode line disposed on at least one lateral side portion of each pixel unit.

4. The array substrate according to claim 2, wherein the common electrode lines and a gate of each transistor are disposed in the same layer.

5. The array substrate according to claim 2, wherein the metal lines and a drain of each transistor are disposed in the same layer.

6. The array substrate according to claim 2, wherein the insulating layer is a gate insulating layer of each transistor;
a passivation layer is disposed between the layer where the metal lines are disposed and a layer where the pixel electrode is disposed; and
the passivation layer is provided with a through hole, and each of the metal lines is electrically connected to the pixel electrode via the through hole.

7. The array substrate according to claim 6, wherein, from a view perpendicular to the array substrate, a projection of the through hole overlaps with the projection of the horizontal branch and/or the vertical branch.

8. The array substrate according to claim 6, wherein each of the pixel units comprises a first display domain, a second display domain, a third display domain and a fourth display domain, the first display domain and the second display domain are disposed in the same row, the third display domain and the fourth display domain are disposed in the same row, the first display domain and the third display domain are disposed in the same column, and the second display domain and the fourth display domain are disposed in the same column.

9. The array substrate according to claim 8, wherein, from a view perpendicular to the array substrate, the projection of the through hole overlaps with at least one among a gap between the first display domain and the second display domain, a gap between the first display domain and the third display domain, a gap between the second display domain and the fourth display domain, and a gap between the third display domain and the fourth display domain.

10. The array substrate according to claim 8, wherein each of the metal lines is disposed within a gap between two adjacent display domains.

11. The array substrate according to claim 1, wherein each of the transistor is a metal oxide transistor, a low-temperature polysilicon transistor, or an amorphous silicon transistor.

12. The array substrate according to claim 1, wherein a range of a width of each metal line is greater than or equal to 2 micrometers and smaller than or equal to 3 micrometers.

13. A display device, comprising:
a control circuit; and
a display panel comprising the array substrate according to claim 1.

14. An array substrate, comprising:
a substrate;
a switch assembly disposed on the substrate, wherein the switch assembly comprises a plurality of transistors;
metal lines;
a pixel electrode comprising a plurality of line-shaped branches, wherein the branches comprises a horizontal branch and a vertical branch perpendicular to each other, and a drain line of each of the transistors is disposed under the horizontal branch closest to said each transistor; and
a plurality of pixel units, wherein each of the pixel units comprises a plurality of display domains, and the display domains of each of the pixel units are symmetrical with respect to the horizontal branch or the vertical branch;
wherein, from a view perpendicular to the array substrate, a projection of each of the metal lines overlaps with a projection of each horizontal branch or each vertical branch on the array substrate;
each pixel unit further comprises a common electrode line and a storage capacitor, and the common electrode lines of the pixel units in the same row are connected to each other;
an insulating layer is disposed between a layer where the metal lines are disposed and a layer where the common electrode lines are disposed, and each common electrode line and the metal lines are respectively functioned as a first electrode and a second electrode of each storage capacitor;
each common electrode line comprises a first common electrode line, and, from a view perpendicular to the array substrate, a projection of the first common electrode line overlaps with a projection of each metal line; and
a range of a width of each metal line is greater than or equal to 2 micrometers and smaller than or equal to 3 micrometers.

15. The array substrate according to claim 14, wherein the common electrode lines and a gate of each transistor are disposed in the same layer.

16. The array substrate according to claim 14, wherein each metal line and a drain of each transistor are disposed in the same layer.

17. The array substrate according to claim 14, wherein each of the pixel units comprises a first display domain, a second display domain, a third display domain and a fourth display domain, the first display domain and the second display domain are disposed in the same row, the third display domain and the fourth display domain are disposed in the same row, the first display domain and the third display domain are disposed in the same column, and the second display domain and the fourth display domain are disposed in the same column.

18. The array substrate according to claim 17, wherein each metal line is disposed within a gap between two adjacent display domains.
